(19) United States
(12) Patent Application Publication
(10) Pub. No.: US 2025/0240983 A1
(43) Pub. Date: Jul. 24, 2025

(54) BUFFERED THIN FILM RESISTOR WITH METAL-INSULATOR-METAL (MIM) INTEGRATION

(71) Applicant: GlobalFoundries Singapore Pte. Ltd., Singapore (SG)

(72) Inventors: Qi Ying WONG, Singapore (SG); Yudi SETIAWAN, Singapore (SG); Bollam Venkata MANGATHAYARU, Singapore (SG); Samuel Chen Wai CHOW, Singapore (SG)

(21) Appl. No.: 18/417,094

(22) Filed: Jan. 19, 2024

(51) Int. Cl. H01L 27/01

(52) U.S. Cl. CPC H10D 1/474; H10D 86/85

(57) ABSTRACT

The present disclosure relates to semiconductor structures and, more particularly, to a buffered thin film resistor (TFR) with metal-insulator-metal (MIM) capacitor integration and methods of manufacture. The structure includes: a first buffer contact on a substrate; a second buffer contact on the substrate, the second buffer contact being on a same wiring level as the first buffer contact; a stack of resistive thin films contacting the first buffer contact and the second buffer contact, the stack of resistive thin films extending on the substrate between the first buffer contact and the second buffer contact; and electrical contacts that are in physical contact to a top plate of the stack of resistive thin films.

### BACKGROUND

The present disclosure relates to semiconductor structures and, more particularly, to a buffered thin film resistor (TFR) with metal-insulator-metal (MIM) capacitor integration and methods of manufacture.

A TFR is a resistor that possesses a thin resistive layer, where the thickness of the thin film resistive layer provides different resistive properties. To create a thin film resistor, a dense, uniform metallic alloy film is deposited onto an insulator material layer. The ceramic-metallic (cermet) alloy film will act as the resistive layer. After the cermet film layer is deposited, it is patterned using photolithography and etching processes, followed by the formation of the electrical contact to the resistive metallic alloy film. High-density resistors in back end of the line (BEOL) integrated with MIM have increased demand due to more need of neuromorphic sensor technology (POLYN). These sensors can be integrated in network arrays of resistance-capacitors (RC) utilized as a filter bank of sensed signals prior to Asynchronous Delta Modulator (ADM) units (i.e., for analog digital conversion).

### SUMMARY

In an aspect of the disclosure, a structure that includes: a first buffer contact on a substrate; a second buffer contact on the substrate, the second buffer contact being on a same wiring level as the first buffer contact; a stack of resistive thin films contacting the first buffer contact and the second buffer contact, the stack of resistive thin films extending on the substrate between the first buffer contact and the second buffer contact; and electrical contacts that are in physical contact to a top plate of the stack of resistive thin films.

In an aspect of the disclosure, a structure comprises a thin film resistor structure between: a first buffer contact on a same wiring level as the first plate of the capacitor; a second buffer contact on the same wiring level as the first buffer contact; and a stack of resistive thin films contacting conductive material of the first buffer contact and the second buffer contact, the stack of resistive thin films being located on the same wiring level as the first buffer contact and the second buffer contact.

In an aspect of the disclosure, a method comprises: forming a first buffer contact and a second buffer contact, the first buffer contact and the second buffer contact each comprise a conductive plate on a substrate; forming a stack of resistive thin films which contacts and extends between the first buffer contact and the second buffer contact; and forming electrical contacts which land on the conductive plate of the first buffer contact and the second buffer contact.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1A-1H show cross-sectional views of steps in the fabrication process of the buffered TFR with MIM integration in accordance with further aspects of the present disclosure.

FIG. 2 shows a perspective side view of regions of the buffered TFR with MIM integration of FIG. 1H in accordance with aspects of the present disclosure.

### DETAILED DESCRIPTION

The present disclosure relates to semiconductor structures and, more particularly, to a buffered TFR with MIM integration and methods of manufacture. In embodiments, the buffered TFR with MIM integration includes buffer contacts and a stack of TFR extending between the buffer contacts, and electrical contacts in physical contact with a conductive plate of the buffer contacts. Advantageously, the structures described herein exhibit increased resistance density, silicon area savings, and tunable resistance and capacitance increase due to multi-layer stacking and serpentine structural design.

In more specific embodiments, the buffered TFR with MIM integration includes multiple regions of stacked TFR utilized to simultaneously manufacture a few different structures. These different semiconductor structures may include stacked TFR in different designs. In embodiments, the stacked TFR is in a serpentine shaped design.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes on the top of a wafer. In particular, the fabrication of the structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

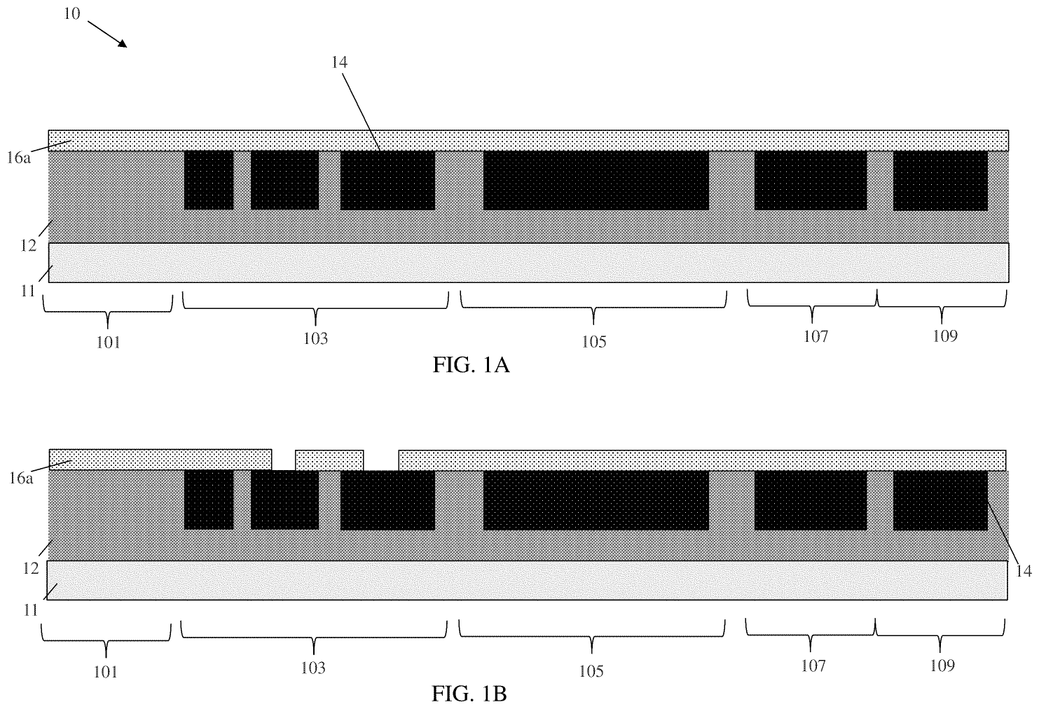

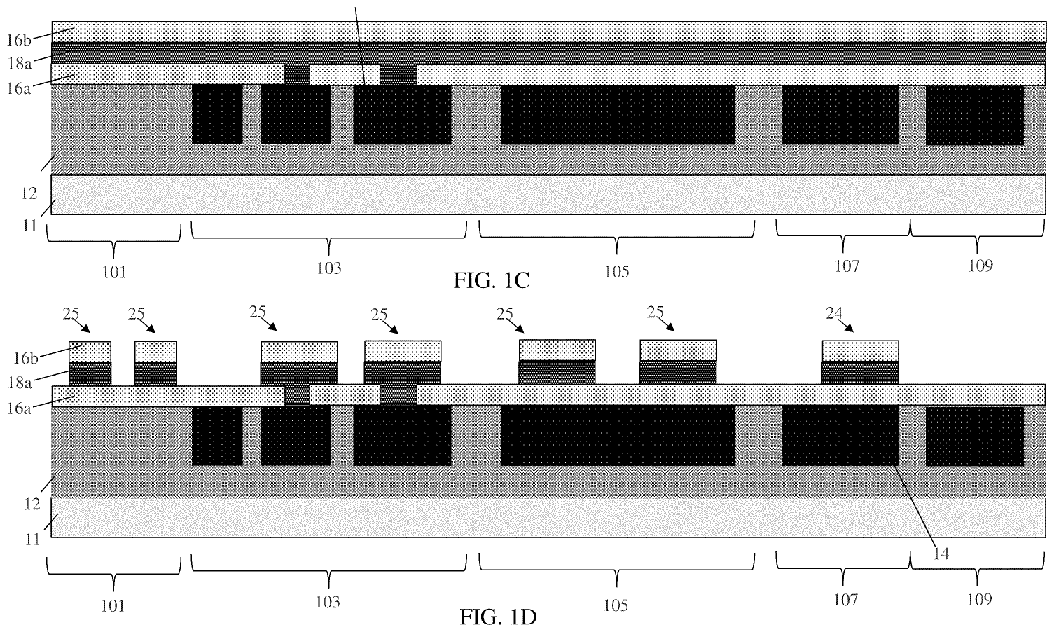

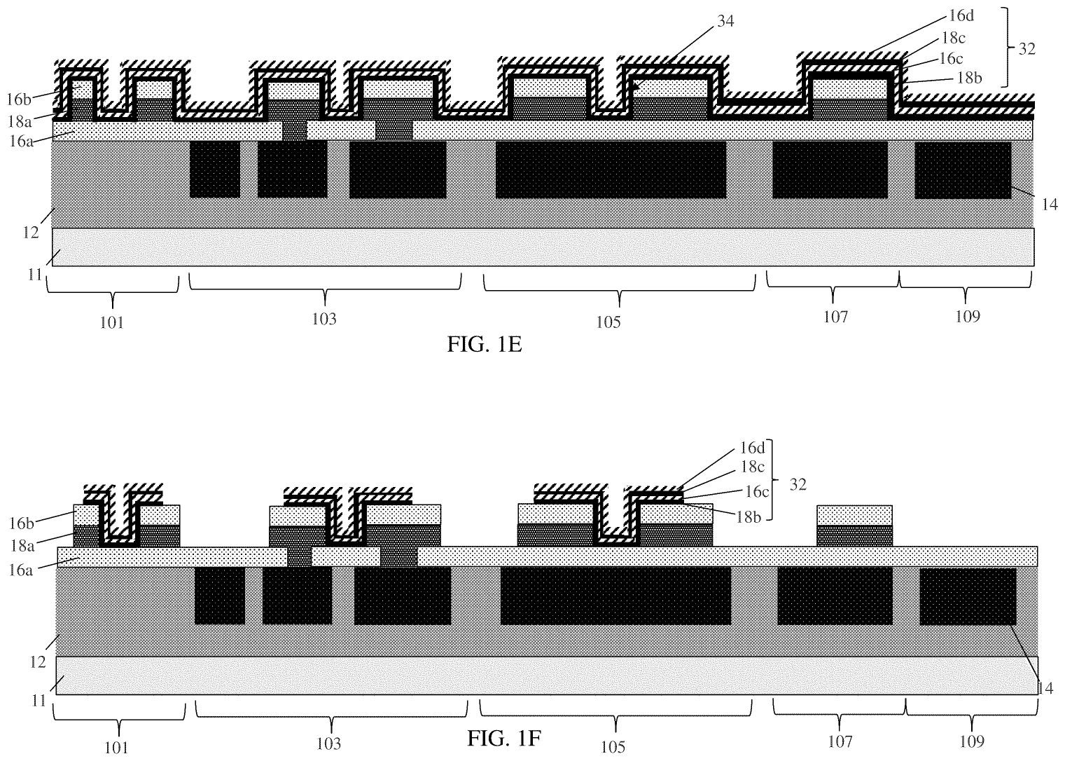

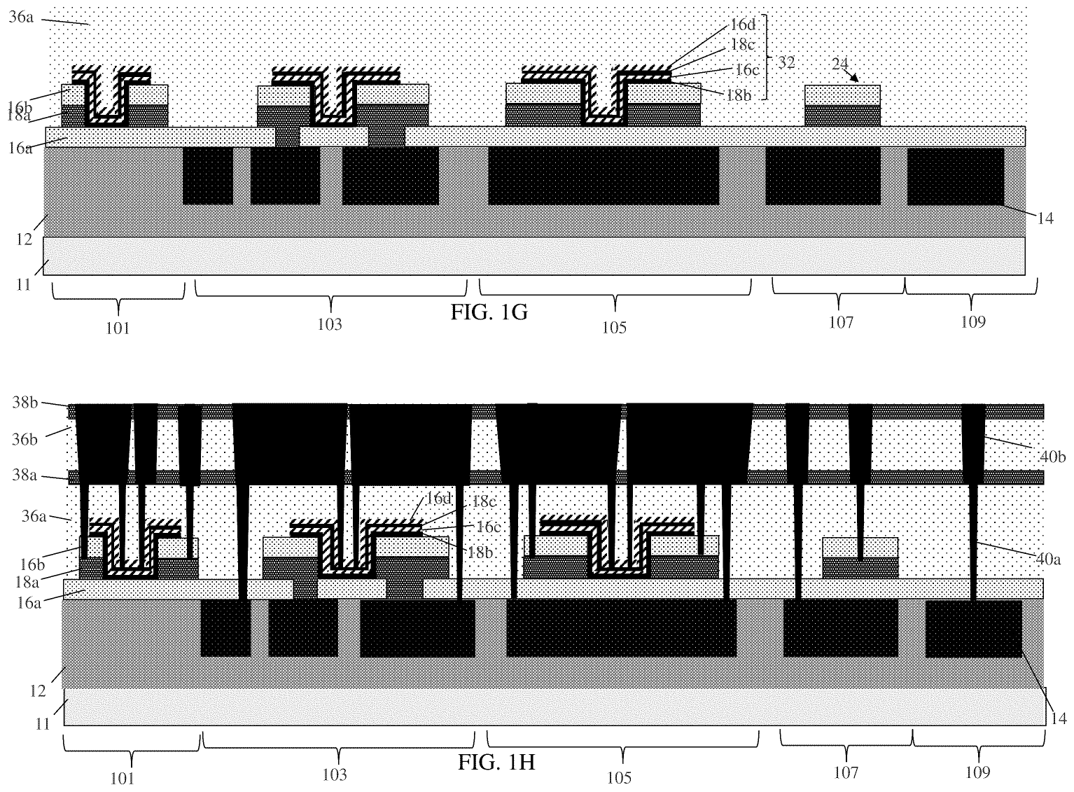

FIG. 1A-1H show cross-sectional views of steps in the fabrication process of the buffered TFR with MIM integration in accordance with further aspects of the present disclosure. The FIGS. 1A-1H include alternating layers of insulator materials 16a, 16b and metal materials 14, 18a (as shown in FIGS. 1E-1H), metal material 18b (as shown in FIGS. 1E-1H), and metal material 18c (as shown in FIGS. 1E-1H). Referring to FIG. 1A, the semiconductor structure 10 shows an ILD material 12 on top of a semiconductor material 11 (e.g., also referred to as a substrate) with regions of stacked materials beginning with a bottom layer of metal material 14 that can be used as a bottom plate for an MIM capacitor. FIGS. 1A-1H show 5 regions from which different structures are created. In embodiments, the regions generated include a stacked TFR region 101, a second stacked TFR region 103, a triple MIM (TMIM) region 105, a MIM region 107, and a logic region 109. The regions 103-109 are simultaneously formed to both increase resistance per unit area and capacitance of the MIM. The top plate of the MIM capacitor being deposited as shown in FIG. 1C. On top of the metal material 14 and ILD material 12, a layer of insulating material 16a can be deposited by any conventional deposition process such as a chemical vapor deposition (CVD) process, amongst others known in the art.

In further embodiments, the interlayer dielectric (ILD) material 12 may be composed of any suitable ILD including, but not limited to, tetraeythlorthosilicate (TEOS), fluorinated tetraethyl orthosilicate (FTEOS), SiCOH, SiO₂, silane, SiN, SiₓO_{y}N_{z}, porous versions of these materials (e.g., pSiCOH) and any other dielectric materials. The ILD material 12 may be additionally be composed any suitable low-k dielectric material

The layers of insulating materials 16a, 16b, 16c (as shown in FIGS. 1E-1H), insulator material 16d (as shown in FIGS. 1E-1H) may be any high-k or low-k dielectric material depending on a specific application and performance parameters. For example, the high-k dielectric material can be, but not limited to, e.g., HfO₂ Al₂O₃, Ta₂O₃, TiO₂, La₂O₃, SrTiO₃, LaAlO₃, ZrO₂, Y₂O₃, Gd₂O₃, and combinations including multilayers thereof. Further, the low-k dielectric can be TEOS, SiCOH, SiO₂, Silane, SiN, SiₓO_{y}N_{z}, material. The layers of insulating material 16a, 16b, 16c, 16d can each be deposited separately to a thickness of about 200 Å to 1000 Å, as an example, with the innermost layer of insulating material 16a being of a different thickness than the other layers of insulator material 16b, 16c, 16d to provide a higher capacitance for the subsequently formed MIM capacitor. The layers of insulator materials 16a, 16b, 16c, 16d can be deposited by any conventional deposition process such as a chemical vapor deposition (CVD) process, amongst others known in the art.

The layers of metal material 14, 18a, 18b, 18c can be any appropriate metal or cermet material used for both MIM capacitors and buffer contacts for a TFR. For example, the layers of metal material 14, 18a, 18b, 18c can be Silicon chromium (SiCr), copper nickel (CuNi), copper chromium (CuCr), nickel chromium (NiCr), titanium nitride (TiN), tantalum nitride (TaN), titanium carbide (TiC), silicon carbide (SiC), tungsten carbide (WC), cobalt (Co), nickel (Ni), chromium (Cr), tungsten (W), molybdenum (Mo), tantalum (Ta), aluminum (Al), or Copper (Cu) although other materials are also contemplated herein. The listed materials may also include impurities typically added to thin film resistors such as oxygen (O₂), nitrogen (N₂), carbon (C), phosphorus (P), among others. In exemplary embodiments, metal material 14 preferably includes Al or Cu. In exemplary embodiments, metal material 18a preferably includes Ta or W.

Still referring to FIG. 1A, a metal material 14 (also referred to as a metallization structure), e.g., wiring structure or interconnect structure, is formed in the ILD material 12 using conventional lithography, etching and deposition methods known to those of skill in the art. In embodiments, the metal material 14 can be deposited by a physical vapor deposition (PVD), a CVD process, or a standard damascene process to a thickness of about 1000 Å to 3000 Å, as an example.

For example, a resist may be formed over the ILD material 12 is exposed to energy (light) to form a pattern (opening). An etching process with a selective chemistry, e.g., reactive ion etching (RIE), will be used to form one or more trenches in the ILD material 12 through the openings of the resist. Following the resist removal by a conventional oxygen ashing process or other known stripants, conductive material (e.g., copper) can be deposited by any conventional deposition processes, e.g., chemical vapor deposition (CVD) processes. Any residual material on the surface of the ILD material 12 can be removed by conventional chemical mechanical polishing (CMP) processes. In another example damascene process, the insulator material 16a may be deposited on ILD material 12 and then etched to form the profile of metal material 14 as shown in FIG. 1A. Then, the profile is filled with the metal material 14 (e.g., copper (Cu)) and excess metal material is removed via CMP.

FIG. 1B shows the patterning of the insulator material 16a which forms the dielectric of an MIM capacitor. In this embodiment, the insulator material 16a are patterned using conventional lithography and etching methods known to those of skill in the art. For example, in the etching processes, selective etch chemistries will be used to separately remove the insulator material 16a through an opening (e.g., pattern) of resist material. In embodiments, the selective chemistry etches the insulator material 16a to selected metal material 14 creating a profile for a buffered contact plug. The sacrificial material for the active device formation can be removed with the selective etch chemistry, while protecting the selected metal material 14 with a masking material known in the art such that no further explanation is required for a complete understanding of the disclosure.

FIG. 1C shows the deposit of the middle plate of the semiconductor structure 10 (i.e., a metal material 18a layer that may include a Cu, Ta, TaN, W, or other metal material plug contacting selected metal material 14). In embodiments, an insulator material 16b is deposited on top of the metal material 18a layer. In one example, the metal material 18a layer may include a TaN material plug. In one example, the insulator material 16b is a SiN cap, or any high-k dielectric

FIG. 1D shows the selective patterning (e.g., etching) of the insulator material 16b and metal material 18a to form buffer contacts 25 and the top plate of the MIM capacitor 24. The buffer contacts 25 are on the same wiring level and are used to avoid punching through during the etching process to form the electrical contact, and extend the contact area of the thin film resistor in order to reduce contact resistance. Accordingly, the buffer contacts 25 include exposed metal material 18a which will contact metal material 18b of the thin film resistor at the bottom of the TFR stack 32 (shown in FIGS. 1E and 1F). The sacrificial material for the active device formation can be removed with the selective etch chemistry, while protecting the selected metal material 14 with a masking material known in the art such that no further explanation is required for a complete understanding of the disclosure.

FIG. 1E shows the deposit of the TFR stack 32 over the patterned structures of FIG. 1D that results in the simultaneous formation of stacked TFR regions 101, 103 and TMIM region 105 with buffered bottom or middle plates. In embodiments, the TFR stack 32 includes a stack of alternating layers of material 18b, 16c, 18c, 16d formed over the buffer contacts 25 and insulating material 16a. The TFR stack 32 including spacer structures 34 between the buffer contacts 25. In embodiments, the TFR stack 32 includes metal material 18b formed over the buffer contacts 25 and insulator material 16a. An alternating stack of insulator material 16c, 16d and metal material 18c is formed over the metal material 18b.

As an example, each of the metal materials 18b, 18c of the TFR stack 32 includes a thickness between 30 Å to 100 Å. The thickness of the insulating materials 16c, 16d layers of the TFR stack 32 may be tuned to the capacitance needed by the semiconductor structure 10. The metal material 18b, 18c layers of the TFR stack 32 may include, in a non-limiting example, SiCr. Further, insulating materials 16c, 16d may include SiN resulting in a TFR stack 32 of SiCr—SiN—SiCr—SiN. The metal materials 18b, 18c of the TFR stack 32 become the top/middle plate of the TMIM in the TMIM region 105.

FIG. 1F shows a single mask formation utilized to etching sections of the stacked TFR 32. In embodiments, the mask can be a hardmask composed of, e.g., SiN. A lithographic mask (e.g., resist) is formed over the masking material and patterned to define the stacked TFR 32. In embodiments, the lithographic mask (e.g., resist) will be patterned to remain partly over the buffer contacts 25. This pattern will protect the stacked TFR 32 to ensure it remains in contact with the exposed side surfaces of the metal material 18a, while also allowing the buffer contacts 25 to be exposed during a subsequent etching process. In this way, the buffer contacts 25 will extend thru the contact area of the stacked TFR 32. The single mask removes the stacked TFR 32 from the MIM region 107 and logic region 109.

FIG. 1G shows an interlevel dielectric material 36a deposited over the MIM capacitor 24, stacked TFR 32 by utilizing conventional deposition methods, e.g., CVD. Following the deposition process, a CMP process is used to planarize the interlevel dielectric material 36a and trenches are formed in the interlevel dielectric material 36a to expose the top and bottom plate of the MIM capacitor 24, the buffer contacts 25, and stacked TFR 32. In example embodiments, the interlevel dielectric material 36a may include tetraeythlorthosilicate (TEOS) or SiCOH deposition utilizing processes known in the art, including low pressure chemical vapor deposition (LPCVD).

FIG. 1H shows formations of contacts 40a, 40b to the metal material 14, MIM capacitor 24, buffer contacts 25, and stacked TFR 32. The contacts 40ab, 40b can be formed by two separate single or dual damascene processes known in the art. For example, an interlevel dielectric material 36a is deposited over the MIM capacitor 24, the buffer contacts 25, and stacked TFR 32. Following the deposition process, a CMP process is used to planarize the interlevel dielectric material 36a and trenches are formed in the interlevel dielectric material 36a to expose the top and bottom plate of the MIM capacitor 24 (including the metal material 14), and the buffer contacts 25 of stacked TFR 32 (e.g., the top plate 18c, metal material 18a, and the metal material 14). Insulating layers 38a, 38b, e.g., SiN, may be deposited and an additional interlevel dielectric material 36b may be deposited over the formed contacts 40a. A CMP process may be utilized to form trenches to the contacts 40a and extend the contacts 40a to include contacts 40b within these new insulating layers 38a, 38b, and 36b.

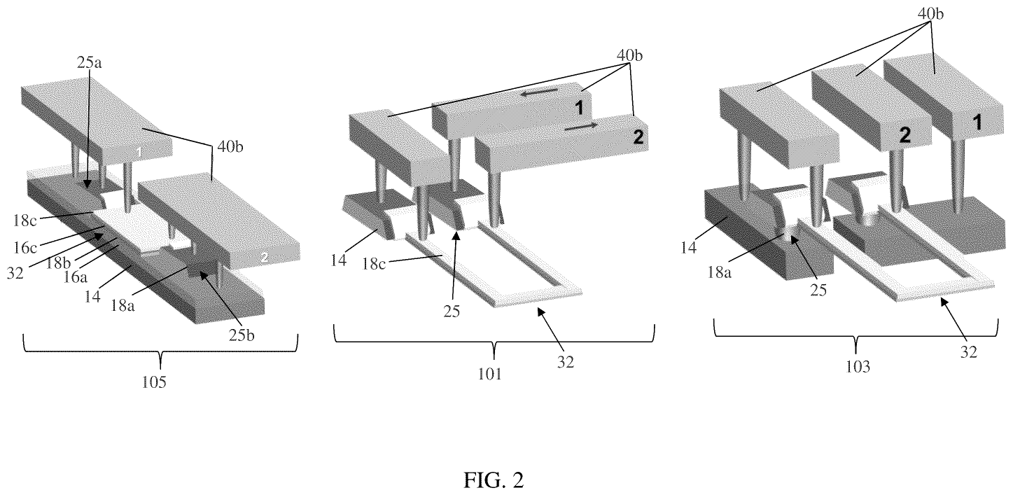

FIG. 2 shows a perspective side view of regions of the buffered TFR with MIM integration of FIG. 1H in accordance with aspects of the present disclosure. FIG. 2 shows the stacked TFR region 101, 103, and TMIM region 105. The structures of the stacked TFR 32, metal material 14, metal material 18a of buffer contacts 25 of these regions 101-105 are shown. The TMIM region 105 includes a more detailed showing of the stacked TFR 32 with the top plate of the TMIM being metal material 18c, middle plate of the TMIM being metal material 18b (including the metal material 18a of the buffer contacts 25 on the same wiring level as the metal material 18b), and bottom plate being the metal material 14. As shown in FIG. 2, stacked TFR region 101 includes a buffer contact 25 that is connected via the top plate of metal material 18c. Further, stacked TFR region 103 includes a metal material 14 connected to buffer contact 25 through a bottom contact. Additionally, the TMIM region 105 includes a buffered middle plate. In particular, the buffered middle plate includes sub buffer contacts 25a and 25b. Further, the TFR 32 stack is between the sub buffer contacts 25a and 25b.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a first buffer contact on a substrate;
a second buffer contact on the substrate, the second buffer contact being on a same wiring level as the first buffer contact;
a stack of resistive thin films contacting the first buffer contact and the second buffer contact, the stack of resistive thin films extending on the substrate between the first buffer contact and the second buffer contact; and
electrical contacts that are in physical contact to a top plate of the stack of resistive thin films.

2. The structure of claim 1, wherein the first buffer contact and the second buffer contact comprise conductive material with insulator material on the conductive material.

3. The structure of claim 2, wherein:
the stack of resistive thin films is on an upper surface of the insulator material on the first buffer contact and the second buffer contact; and
the stack of resistive thin films physically contacts a side surface of the conductive material of the first buffer contact and the second buffer contact.

4. The structure of claim 3, wherein:
the electrical contacts are in physical contact with the conductive material of the first buffer contact and the second buffer contact.

5. The structure of claim 3, further comprising spacers on the first buffer contact and the second buffer contact, the spacers comprising the stack of resistive thin films and insulating material over each layer of the stack of resistive thin films.

6. The structure of claim 5, wherein the insulating material also covers the stack of resistive thin films between and over the first buffer contact and the second buffer contact.

7. The structure of claim 5, wherein the spacers are on sides of the first buffer contact and the second buffer contact, which oppose a side surface of the conductive material which contacts the resistive thin films.

8. The structure of claim 1, wherein the first buffer contact and the second buffer contact are of a same material and are on a same wiring level as a plate of a metal-insulator-metal capacitor.

9. The structure of claim 8, wherein the stack of resistive thin films comprises SiCr—SiN—SiCr—SiN layers.

10. The structure of claim 8, wherein the top plate and a bottom plate include spacer structures comprising the resistive thin films and the insulating material, the insulating material also covering each layer of the stack of resistive thin films.

11. The structure of claim 8, wherein the first buffer contact and the second buffer contact comprise TaN.

12. The structure of claim 11, wherein the electrical contacts are in physical contact with a metallization structure.

13. A structure comprising:
a thin film resistor structure between:
a first buffer contact on a same wiring level as the first plate of the capacitor;
a second buffer contact on the same wiring level as the first buffer contact; and
a stack of resistive thin films contacting conductive material of the first buffer contact and the second buffer contact, the stack of resistive thin films being located on the same wiring level as the first buffer contact and the second buffer contact.

14. The structure of claim 13, wherein the first buffer contact and the second buffer contact are composed of a conductive material with insulator material on the conductive material.

15. The structure of claim 14, further comprising spacers on a side surface of the first buffer contact and the second buffer contact, wherein the spacers comprise the resistive thin films and the insulating material over each layer of the stack of resistive thin films.

16. The structure of claim 14, wherein:
the first buffer contact and the second buffer contact comprise the insulator material on the conductive material;
the stack of resistive thin films is on an upper surface of the insulator material of the first buffer contact and the second buffer contact; and
the stack of resistive thin films physically contacts a side surface of the conductive material of the first buffer contact and the second buffer contact.

17. The structure of claim 16, further comprising the electrical contacts being in physical contact with the conductive material of the first buffer contact and the second buffer contact.

18. The structure of claim 16, further comprising spacers on the first buffer contact and the second buffer contact, wherein:
the spacers comprise the resistive thin films and the insulating material; and
the spacers are on sides of the first buffer contact and the second buffer contact, which oppose the side surface of the conductive material which contact the resistive thin films.

19. The structure of claim 13, wherein the stack of resistive thin films comprises SiCr—SiN—SiCr—SiN layers.

20. A method comprising:
forming a first buffer contact and a second buffer contact, the first buffer contact and the second buffer contact each comprise a conductive plate on a substrate;
forming a stack of resistive thin films which contacts and extends between the first buffer contact and the second buffer contact; and
forming electrical contacts which land on the conductive plate of the first buffer contact and the second buffer contact.
